(19) United States
(12) Patent Application Publication
(10) Pub. No.: US 2015/0263179 A1
(43) Pub. Date: Sep. 17, 2015

(54) SEMICONDUCTOR DEVICE

(71) Applicant: Kabushiki Kaisha Toshiba, Tokyo (JP)

(72) Inventors: Masaru FURUKAWA, Himeji Hyogo (JP); Hideo YOSHIHASHI, Ibo Hyogo (JP)

(73) Assignee: KABUSHIKI KAISHA TOSHIBA, Tokyo (JP)

(21) Appl. No.: 14/453,212

(22) Filed: Aug. 6, 2014

(30) Foreign Application Priority Data
Mar. 14, 2014 (JP) 2014-051820

(51) Int. Cl. H01L 29/868; H01L 21/268; H01L 21/3205; H01L 29/739; H01L 29/06; H01L 29/45

(52) U.S. Cl. CPC H01L 29/868; H01L 29/0692; H01L 29/45; H01L 21/32053; H01L 29/7393; H01L 21/268

(57) ABSTRACT

A semiconductor device includes a first electrode, a second electrode, a first conductivity-type first semiconductor region between the first electrode and the second electrode, a first conductivity-type second semiconductor region between the first electrode and the first semiconductor region, the second semiconductor region having a dopant concentration that is higher than a dopant concentration of the first semiconductor region, the second semiconductor region including a silicide layer in contact with the first electrode, and a second conductivity-type third semiconductor region between the first semiconductor region and the second electrode.

### CROSS-REFERENCE TO RELATED APPLICATION

This application is based upon and claims the benefit of priority from Japanese Patent Application No. 2014-051820, filed Mar. 14, 2014, the entire contents of which are incorporated herein by reference.

### BACKGROUND

In a pin diode, if the balance between the amount of positive holes that are injected from the anode side and the amount of electrons that are injected from the cathode side is not achieved, a flat carrier concentration distribution profile is not obtained in the direction from the anode side to the cathode side and there maybe a decrease in the recovery speed.

There are some pin diode configurations that achieve a balance between the carrier amounts that are injected from both electrodes by reducing the carrier amount to be injected by separating a semiconductor region (a p-type semiconductor region or an n-type semiconductor region) on any one pole side. As a result, a flatter carrier concentration distribution profile is obtained. However, a mask layer formation process to form a separated semiconductor region is needed and it is not possible to easily reduce cost with such pin diode configurations. Moreover, if the semiconductor region is separated into a plurality of regions, a current path may decrease, resulting in an increase in ON resistance.

### DESCRIPTION OF THE DRAWINGS

FIG. 1A is a schematic sectional view illustrating a semiconductor device according to a first embodiment and FIG. 1B is a schematic plan view illustrating the semiconductor device according to the first embodiment.

FIG. 2 is a schematic sectional view illustrating a method for forming a silicide layer in a semiconductor device according to the first embodiment.

FIG. 3A is a schematic sectional view illustrating the operation of a semiconductor device according to a first reference example and FIG. 3B is a schematic sectional view illustrating the operation of a semiconductor device according to a second reference example.

FIG. 4 is a schematic sectional view illustrating the operation of the semiconductor device according to the first embodiment.

FIG. 5 is a schematic sectional view illustrating a semiconductor device according to a second embodiment.

### DETAILED DESCRIPTION

Embodiments provide a semiconductor device that may improve the recovery speed and reduce ON resistance.

In general, according to one embodiment, a semiconductor device includes a first electrode, a second electrode, a first conductivity-type first semiconductor region between the first electrode and the second electrode, a first conductivity-type second semiconductor region between the first electrode and the first semiconductor region, the second semiconductor region having a dopant concentration that is higher than a dopant concentration of the first semiconductor region, the second semiconductor region including a silicide layer in contact with the first electrode, and a second conductivity-type third semiconductor region between the first semiconductor region and the second electrode.

Hereinafter, with reference to the drawings, embodiments will be described. In the following description, the same members will be identified with the same characters, and the description of the already-explained member will be appropriately omitted.

### First Embodiment

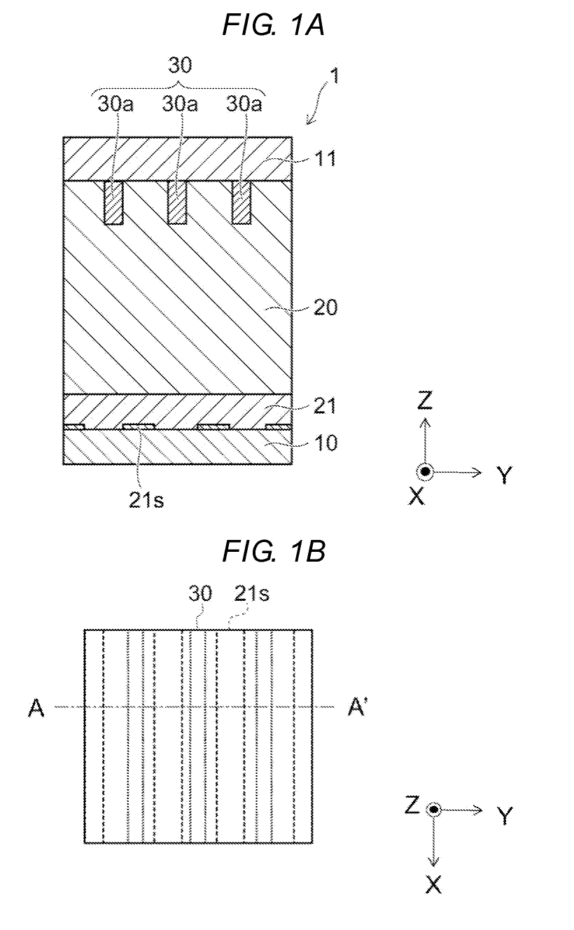

FIG. 1A is a schematic sectional view illustrating a semiconductor device according to a first embodiment, and FIG. 1B is a schematic plan view illustrating a semiconductor device according to the first embodiment.

Here, in FIG. 1A, a cross section taken along the line A-A′ of FIG. 1B is illustrated.

A semiconductor device 1 is a pin diode having an upper-and-lower-electrode structure.

The semiconductor device 1 includes a cathode electrode 10 (a first electrode) and an anode electrode 11 (a second electrode). Between the cathode electrode 10 and the anode electrode 11, an n⁻-type semiconductor region 20 (a first semiconductor region) is provided. The semiconductor region 20 corresponds to an i region of the pin diode. Between the cathode electrode 10 and the semiconductor region 20, an n⁺-type semiconductor region 21 (a second semiconductor region) is provided. The dopant concentration of the semiconductor region 21 is higher than the dopant concentration of the semiconductor region 20. The semiconductor region 21 is in contact with the cathode electrode 10.

The semiconductor region 21 includes a plurality of silicide layers 21s on the side of the cathode electrode 10. The plurality of silicide layers 21s are arranged in a direction (Y direction) intersecting with (in one embodiment, orthogonal to) a direction (Z direction) from the cathode electrode 10 to the anode electrode 11. The plurality of silicide layers 21s form an ohmic contact with the cathode electrode 10. A portion of the semiconductor region 21 in which the semiconductor region 21 directly contacts the cathode electrode 10 may not necessarily form an ohmic contact. For example, the contact resistance between the plurality of silicide layers 21s and the cathode electrode 10 is lower than the contact resistance between the semiconductor region 21 and the cathode electrode 10.

Between the semiconductor region 20 and the anode electrode 11, a p⁺-type semiconductor region 30 (a third semiconductor region) is provided. The semiconductor region 30 is formed of a plurality of regions 30a, and the plurality of regions 30a are arranged in the Y direction. The semiconductor region 30 and the silicide layers 21s extend in the X direction intersecting with (in one embodiment, orthogonal to) the Z direction and the Y direction (FIG. 1B).

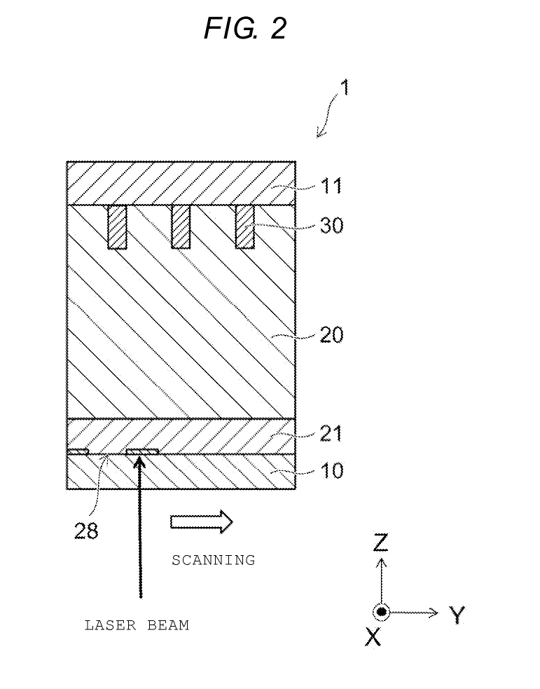

FIG. 2 is a schematic sectional view illustrating a method for forming the silicide layer in a semiconductor device according to the first embodiment.

The plurality of silicide layers 21s are formed by irradiating a junction 28 between the cathode electrode 10 and the semiconductor region 21 with a laser. In the location of the junction 28 that is locally irradiated with the laser, a silicon component of the semiconductor region 21 reacts with a metal component of the cathode electrode 10 by the application of heat by the laser. As a result, the silicide layers 21s are formed.

As used herein, the n⁺-type, the n-type, and the n⁻-type may be referred to as a first conductivity type, and the p⁺-type and the p-type may be referred to as a second conductivity type. Here, the dopant concentration becomes lower in the order of the n⁺-type, the n-type, and the n⁻-type and in the order of the p⁺-type and the p-type.

The “dopant concentration” described above refers to the effective concentration of dopant elements that contributes to the conductivity of a semiconductor material. For example, when the semiconductor material contains a dopant element which becomes a donor and a dopant element which becomes an acceptor, the concentration of the activated dopant elements from which the dopant elements canceled out as the donor and the acceptor are removed is used as the dopant concentration.

The principal ingredients of the semiconductor region 20, the semiconductor region 21, and the semiconductor region 30 are, for example, silicon carbide (SiC), silicon (Si), and so forth.

When the principal ingredient of the semiconductor material of the semiconductor device 1 is silicon carbide (SiC), as a first conductivity-type dopant element, for example, nitrogen (N) or the like is adopted. As a second conductivity-type dopant element, for example, aluminum (Al) or the like is adopted.

When the principal ingredient of the semiconductor material of the semiconductor device 1 is silicon (Si), as a first conductivity-type dopant element, for example, phosphorus (P), arsenic (As), or the like is adopted. As a second conductivity-type dopant element, for example, boron (B) or the like is adopted.

The material of the cathode electrode 10 and the anode electrode 11 is metal containing at least one selected from the group of, for example, aluminum (Al), titanium (Ti), nickel (Ni), tungsten (W), molybdenum (Mo), copper (Cu), gold (Au), platinum (Pt), and so forth. These metals may have a laminate structure.

Moreover, each silicide layer 21s is a layer obtained by silicidizing at least one metal selected from the group of aluminum (Al), titanium (Ti), nickel (Ni), tungsten (W), molybdenum (Mo), copper (Cu), gold (Au), platinum (Pt), and so forth.

Prior to description of the operation of the semiconductor device 1, the operation of a semiconductor device according to a reference example will be described.

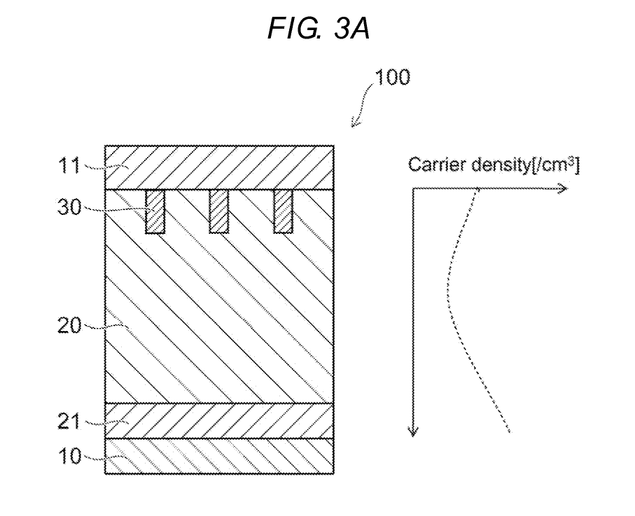

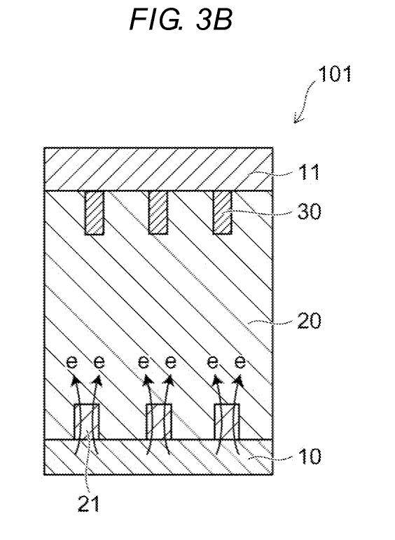

FIG. 3A is a schematic sectional view illustrating the operation of a semiconductor device according to a first reference example, and FIG. 3B is a schematic sectional view illustrating the operation of a semiconductor device according to a second reference example.

In a semiconductor device 100 illustrated in FIG. 3A, the entire area of the semiconductor region 21 forms an ohmic contact with the cathode electrode 10 by annealing. In the semiconductor device 100, a forward bias voltage by which the potential of the anode electrode 11 becomes higher than the potential of the cathode electrode 10 is applied between the anode electrode 11 and the cathode electrode 10. In this case, the semiconductor device 100 performs a bipolar operation in which a positive hole is injected into the semiconductor region 20 from the anode electrode 11 and an electron is injected into the semiconductor region 20 from the cathode electrode 10.

In the semiconductor device 100, the entire area of the semiconductor region 21 forms an ohmic contact with the cathode electrode 10. In such a structure, as illustrated in a carrier concentration profile on the right side of FIG. 3A, the balance between the amount of positive holes that are injected from the anode side and the amount of electrons that are injected from the cathode side is not achieved (the amount of positive holes<the amount of electrons), and sometimes a flat carrier concentration distribution profile is not obtained. As a result, during recovery operation which is performed after the semiconductor device 100 is caused to transition from the turn-on state to the turn-off state, the carriers remaining in the semiconductor device are not efficiently ejected into both electrodes, which may result in a decrease in the recovery speed.

To prevent this, in a semiconductor device 101 illustrated in FIG. 3B, the semiconductor region 21 is separated in the Y direction. With such a structure, since the volume of the semiconductor region 21 is reduced as compared to that of FIG. 3A, an injection of electrons from the cathode side is suppressed. Therefore, as compared to FIG. 3A, it can obtain a flatter carrier concentration distribution profile.

However, electrons (e) that are injected from the cathode electrode 10 are concentrated in the semiconductor region 21 whose potential is the lowest for the electrons and then flow into the semiconductor region 20. As a result, there is a possibility that resistance is increased upon turn-on.

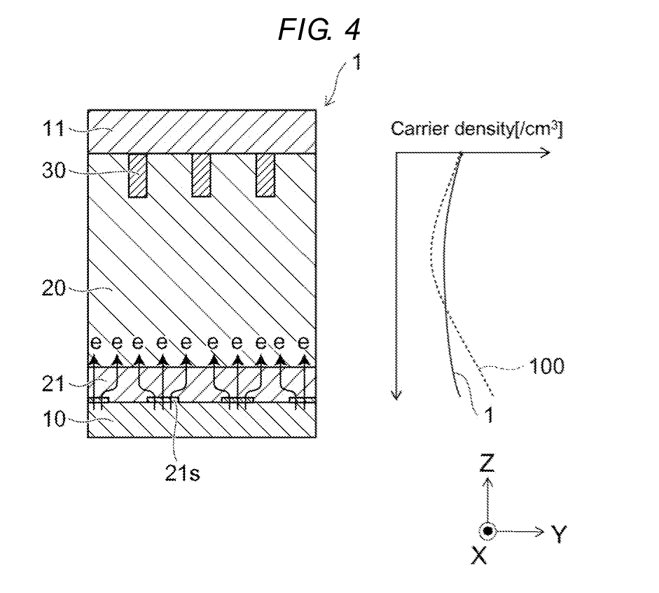

FIG. 4 is a schematic sectional view illustrating the operation of the semiconductor device according to the first embodiment.

In the semiconductor device 1 illustrated in FIG. 4, a forward bias voltage by which the potential of the anode electrode 11 becomes higher than the potential of the cathode electrode 10 is applied between the anode electrode 11 and the cathode electrode 10. In this case, the semiconductor device 1 performs a bipolar operation in which a positive hole is injected into the semiconductor regions from the anode electrode 11 and an electron is injected into the semiconductor regions from the cathode electrode 10.

In the semiconductor device 1, the separated silicide layers 21s forming an ohmic contact with the cathode electrode 10 are provided and disposed in the semiconductor region 21. With such a structure, since the junction area between the semiconductor region 21 and the cathode electrode 10 at which an ohmic contact is formed is reduced as compared to that of FIG. 3A, an injection of electrons from the cathode side is suppressed. Therefore, as compared to FIG. 3A, it can obtain a flatter carrier concentration distribution profile (the diagram on the right side of FIG. 4). As a result, it is possible to achieve a faster recovery speed than the reference example of FIG. 3A.

Moreover, immediately after passing through a region of ohmic contact, electrons (e) that are injected from the cathode electrode 10 reach the high-concentration semiconductor region 21, that is, the low-resistance semiconductor region 21. In this low-resistance semiconductor region 21, since the electrons are easily diffused in both the X direction and the Y direction and then flow into the semiconductor region 20, the resistance upon turn-on is further reduced. That is, in the semiconductor device 1, the recovery speed becomes faster as compared the reference example of FIG. 3A and the resistance upon turn-on is reduced as compared the reference example of FIG. 3B.

In the semiconductor device 1, as for a portion in which the semiconductor region 21 and the cathode electrode 10 directly contact with each other, when a surge current flows through the semiconductor device 1, for example, an adjustment may be made so as to obtain an energy barrier with which this surge current may be swiftly released into the electrode. By doing so, a breakdown of a device by the surge current is prevented. The energy barrier may also be adjusted by laser irradiation.

Moreover, as for the formation of the silicide layers 21s, it is also possible to use the photo engraving process (PEP). For example, this is a method by which the silicide layers 21s are formed on the back side of the semiconductor region 21 by heating, after selectively forming a nickel film on the back side of the semiconductor region 21, the semiconductor region 21 and the nickel film. This method may also be used in forming the semiconductor device according to the embodiment.

However, the laser irradiation allows the design of the silicide layers 21s to be changed ex-post facto and provides higher design flexibility. For example, even after the silicide layers 21s are formed, it is possible to increase the width thereof easily by performing laser irradiation again. Moreover, performing the laser irradiation eliminates the necessity for the PEP. Because of this, it is possible to reduce cost when the laser irradiation method is used.

### Second Embodiment

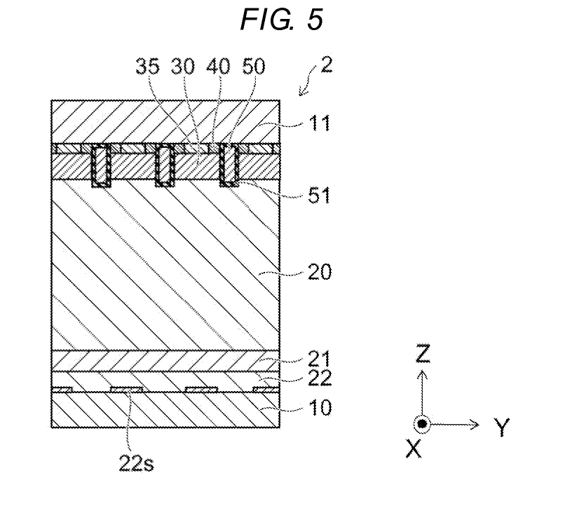

FIG. 5 is a schematic sectional view illustrating a semiconductor device according to a second embodiment. A silicide layer formed by laser irradiation is applied not only to a diode but also to a switching element.

A semiconductor device 2 illustrated in FIG. 5 is an IGBT having an upper-and-lower-electrode structure. The semiconductor device 2 includes a collector electrode 10 (a first electrode) and an emitter electrode 11 (a second electrode). Between the collector electrode 10 and the emitter electrode 11, an n⁻-type drift region 20 (a first semiconductor region) is provided. Between the collector electrode 10 and the drift region 20, an n⁺-type collector region 21 (a second semiconductor region) is provided. The dopant concentration of the collector region 21 is higher than the dopant concentration of the drift region 20.

Between the collector electrode 10 and the collector region 21, a p⁺-type collector region 22 (a third semiconductor region) is provided. The collector region 22 includes a plurality of silicide layers 22s. The plurality of silicide layers 22s are in contact with the collector electrode 10 and are arranged in the Y direction intersecting with the Z direction from the collector electrode 10 to the emitter electrode 11. The contact resistance between the plurality of silicide layers 22s and the collector electrode 10 is lower than the contact resistance between the collector region 22 and the collector electrode 10.

Between the drift region 20 and the emitter electrode 11, a p-type base region 30 (a fourth semiconductor region) is provided. The dopant concentration of the base region 30 is lower than the dopant concentration of the collector region 22. Between the base region 30 and the emitter electrode 11, an n⁺-type emitter region 40 (a fifth semiconductor region) is provided. The dopant concentration of the emitter region 40 is higher than the dopant concentration of the drift region 20. Moreover, p⁺-type semiconductor regions 35 are in contact with the emitter region 40.

A gate electrode 50 (a third electrode) is in contact with the emitter region 40, the base region 30, and the drift region 20 with a gate insulating film 51 being interposed between the gate electrode 50 and the emitter region 40, the base region 30, and the drift region 20.

Also in the semiconductor device 2, the plurality of silicide layers 22s are formed by irradiating a junction between the collector electrode 10 and the collector region 22 with a laser.

The principal ingredients of the drift region 20, the collector region 21, the collector region 22, the base region 30, the emitter region 40, and the semiconductor regions 35 are, for example, silicon carbide (SiC), silicon (Si), and so forth.

When the principal ingredient of the semiconductor material of the semiconductor device 2 is silicon carbide (SiC), as a first conductivity-type dopant element, for example, nitrogen (N) or the like is adopted. As a second conductivity-type dopant element, for example, aluminum (Al) or the like is adopted.

When the principal ingredient of the semiconductor material of the semiconductor device 2 is silicon (Si), as a first conductivity-type dopant element, for example, phosphorus (P), arsenic (As), or the like is adopted. As a second conductivity-type dopant element, for example, boron (B) or the like is adopted.

The material of the collector electrode 10 and the emitter electrode 11 is metal including at least one selected from the group of aluminum (Al), titanium (Ti), nickel (Ni), tungsten (W), molybdenum (Mo), copper (Cu), gold (Au), platinum (Pt), and so forth. These metals may have a laminate structure.

Moreover, each silicide layer 22s is a layer obtained by silicidizing at least one metal selected from the group of aluminum (Al), titanium (Ti), nickel (Ni), tungsten (W), molybdenum (Mo), copper (Cu), gold (Au), platinum (Pt), and so forth.

The gate electrode 50 includes polysilicon, metal, or the like to which a dopant element is introduced. Moreover, in the embodiment, the insulating film is an insulating film including, for example, silicon oxide (SiOₓ), silicon nitride (SiNₓ), or the like.

In the semiconductor device 2, a voltage is applied between the collector electrode 10 and the emitter electrode 11 in such a way that the potential of the collector electrode 10 becomes higher than the potential of the emitter electrode 11. Then, a potential higher than a threshold potential is supplied to the gate electrode 50, and a channel is formed in the base region 30 along the gate insulating film 51. That is, the semiconductor device 2 is brought to an ON state.

In this case, the semiconductor device 2 performs a bipolar operation in which a positive hole is injected into the drift region 20 from the collector electrode 10 and an electron is injected into the drift region 20 from the emitter electrode 11 via the channel.

In the semiconductor device 2, the separated silicide layers 22s forming an ohmic contact with the collector electrode 10 are provided and disposed in the collector region 22. With such a structure, since the junction area at which an ohmic contact is formed is reduced as in the semiconductor device 1, an injection of positive holes from the collector side is suppressed. Therefore, it can obtain a flatter carrier concentration distribution profile. As a result, it is possible to obtain a faster switching speed.

Moreover, immediately after passing through a region forming an ohmic contact, electrons (e) that are injected from the collector electrode 10 reach the high-concentration, that is, the low-resistance collector region 22. In this low-resistance collector region 22, since the positive holes are easily diffused in both the X direction and the Y direction and then flow into the drift region 20 after diffusion, the resistance upon ON is further reduced. That is, in the semiconductor device 2, the switching speed becomes faster and the resistance upon ON is further reduced.

In the embodiments described above, “on” in the description “a part A is provided on a part B” covers, covers a case where the part A is not in contact with the part B and the part A is provided above the part B in addition to a case where the part A is in contact with the part B. Moreover, “a part A is provided on a part B” is sometimes applied to a case where the part A is located under the part B, not on the part B, and a case where the part A and the part B are arranged side by side. This is because, even when the semiconductor device according to the embodiment is rotated, the structure of the semiconductor device is not changed from the structure before rotation.

The embodiments are described above with reference to the specific examples. However, the embodiments are not limited to these specific examples. That is, what is obtained as a result of a person skilled in the art making design change to these specific examples is also included in the scope of the embodiments as long as what is obtained has the feature of the embodiments. The elements of the specific examples described above and the placement, materials, conditions, shapes, sizes, and so forth of the elements are not limited to those described above and may be changed as appropriate.

Moreover, the elements of each embodiment described above may be combined where technically possible, and what is obtained by combining these elements is also included in the scope of the embodiment as long as what is obtained has the feature of the embodiment. In addition, a person skilled in the art may conceive of various examples of changes and modifications in the scope of the idea of the embodiments, and these examples of changes and modifications are also construed as being included in the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode;
a first conductivity-type first semiconductor region between the first electrode and the second electrode;
a first conductivity-type second semiconductor region between the first electrode and the first semiconductor region, the second semiconductor region having a dopant concentration that is higher than a dopant concentration of the first semiconductor region, the second semiconductor region including a silicide layer in contact with the first electrode; and
a second conductivity-type third semiconductor region between the first semiconductor region and the second electrode.

2. The semiconductor device according to claim 1, wherein
a contact resistance between the silicide layer and the first electrode is lower than a contact resistance between the second semiconductor region and the first electrode.

3. The semiconductor device according to claim 1, wherein
the third semiconductor region is formed of a plurality of regions, and
the plurality of regions are respectively arranged in a direction intersecting a direction from the first electrode to the second electrode.

4. The semiconductor device according to claim 1, wherein
the silicide layer includes a plurality of silicide layers, and
the silicide layers are respectively arranged in a direction intersecting a direction from the first electrode to the second electrode.

5. The semiconductor device according to claim 4, wherein the first electrode is alternately in contact with the silicide layers and portions of the second semiconductor region at a junction between the first electrode and the second semiconductor region.

6. The semiconductor device according to claim 5, wherein the first electrode and the silicide layers form ohmic contacts.

7. The semiconductor device according to claim 5, wherein
the silicide layer is formed by irradiating the junction between the first electrode and the second semiconductor region with a laser.

8. A semiconductor device comprising:
a first electrode;
a second electrode;
a first conductivity-type first semiconductor region between the first electrode and the second electrode;
a first conductivity-type second semiconductor region between the first electrode and the first semiconductor region, the second semiconductor region having a dopant concentration being higher than a dopant concentration of the first semiconductor region;
a second conductivity-type third semiconductor region between the first electrode and the second semiconductor region, and including a silicide layer in contact with the first electrode;
a second conductivity-type fourth semiconductor region between the first semiconductor region and the second electrode, the fourth semiconductor region whose dopant concentration being lower than a dopant concentration of the third semiconductor region;
a first conductivity-type fifth semiconductor region between the fourth semiconductor region and the second electrode, the fifth semiconductor region having a dopant concentration that is higher than a dopant concentration of the first semiconductor region; and
a third electrode that is in contact with the fifth semiconductor region, the fourth semiconductor region, and the first semiconductor region with an insulating film being interposed between the third electrode, and the fifth semiconductor region, the fourth semiconductor region and the first semiconductor region.

9. The semiconductor device according to claim 8, wherein
a contact resistance between the silicide layer and the first electrode is lower than a contact resistance between the third semiconductor region and the first electrode.

10. The semiconductor device according to claim 8, wherein
the silicide layer includes a plurality of silicide layers, and
the silicide layers are respectively arranged in a direction intersecting a direction from the first electrode to the second electrode.

11. The semiconductor device according to claim 10, wherein the first electrode is alternately in contact with the silicide layers and portions of the third semiconductor region at a junction between the first electrode and the third semiconductor region.

12. The semiconductor device according to claim 11, wherein the first electrode and the silicide layers form ohmic contacts.

13. The semiconductor device according to claim 11, wherein
the silicide layer is formed by irradiating the junction between the first electrode and the third semiconductor region with a laser.

14. The semiconductor device according to claim 8, further comprising:
a second conductivity-type sixth semiconductor region between the fourth semiconductor region and the second electrode, the sixth semiconductor region having a dopant concentration that is higher than a dopant concentration of the fourth semiconductor region.

15. The semiconductor device according to claim 14, wherein the sixth semiconductor region is between portions of the fifth semiconductor region in a direction intersecting a direction from the first electrode to the second electrode.

16. A method of forming a semiconductor device having a first electrode, a second electrode, a first conductivity-type first semiconductor region between the first electrode and the second electrode, a first conductivity-type second semiconductor region between the first electrode and the first semiconductor region, the second semiconductor region having a dopant concentration that is higher than a dopant concentration of the first semiconductor region, and a second conductivity-type third semiconductor region between the first semiconductor region and the second electrode, said method comprising:
selectively forming a silicide layer at a junction between the first electrode and the second semiconductor electrode.

17. The method of claim 16, wherein the silicide layer is formed by irradiating the junction with a laser beam.

18. The method of claim 16, wherein the silicide layer is formed by a photo engraving process.

19. The method of claim 16, wherein
a contact resistance between the silicide layer and the first electrode is lower than a contact resistance between the second semiconductor region and the first electrode.

20. The method of claim 16, wherein
the silicide layer includes a plurality of silicide layers, and
the silicide layers are respectively arranged in a direction intersecting a direction from the first electrode to the second electrode.
